(19) United States
(12) Patent Application Publication
(10) Pub. No.: US 2005/0154950 A1
(43) Pub. Date: Jul. 14, 2005

(54) Method for saving self-test output to both flash and media

(76) Inventors: Mine Budiman, Livermore, CA (US); Helen Clint, San Jose, CA (US); Stephen G. Paul, Santa Cruz, CA (US); Fernando A. Zayas, Loveland, CO (US)

Correspondence Address: FLIESLER MEYER, LLP, FOUR EMBARCADERO CENTER, SUITE 400, SAN FRANCISCO, CA, 94111, US

(21) Appl. No.: 10/891,841

(22) Filed: Jul. 15, 2004

Related U.S. Application Data
(60) Provisional application No. 60/532,464, filed on Dec. 24, 2003.
(60) Provisional application No. 60/532,422, filed on Dec. 24, 2003.

(51) Int. Cl. G01R 31/28

(52) U.S. Cl. 714/733

(57) ABSTRACT

A hard disk drive includes a flash memory and a rotatable disk. During self-test, self-test data is written first to flash and then later written to the rotatable disk. Since the self-test data is stored in the flash, if there is a power failure the hard disk drive can recover without repeating the test.

### CLAIM OF PRIORITY

This application claims priority to U.S. Provisional Application No. 60/532,464 entitled “Saving Self-test Output to Both Flash and Media”, filed Dec. 24, 2003 and U.S. Provisional Application No. 60/532,422 entitled “Method for Saving Self-test Output to Both Flash and Media”, filed Dec. 24, 2003.

### FIELD OF THE INVENTION

The present invention relates to rotating media storage devices.

### BACKGROUND

Rotating media storage devices, such as hard disk drives, are an integral part of computers and other devices with needs for large amounts of reliable memory. Rotating media storage devices are inexpensive, relatively easy to manufacture, forgiving where manufacturing flaws are present, and capable of storing large amounts of information in relatively small spaces.

A typical rotating media storage device having a rotatable storage medium includes a head disk assembly and electronics to control operation of the head disk assembly. The head disk assembly can include one or more disks. In a magnetic disk drive, a disk includes a recording surface to receive and store user information. The recording surface can be constructed of a substrate of metal, ceramic, glass or plastic with a very thin magnetizable layer on either side of the substrate. Data is transferred to and from the recording surface via a head mounted on an arm of the actuator assembly. Heads can include one or more read and/or write elements, or read/write elements, for reading and/or writing data. Drives can include one or more heads for reading and/or writing. In magnetic disk drives, heads can include a thin film inductive write element and a magneto-resistive read element. An actuator, such as a Voice Coil Motor (VCM), is used to position the head assembly over the correct track on a disk by rotating the arm.

### SUMMARY

One embodiment of the present invention is a hard disk drive where self-test data is stored to a flash memory on the hard disk drive and later written to a rotatable disk of the hard disk drive. Since the flash is not volatile memory, if power fails after the self-test data for a test is written to the flash, then the test need not be repeated. This potentially saves hours of time.

### BRIEF DESCRIPTIONS OF THE DRAWINGS

FIG. 1 is a diagram of a rotating media storage device of one embodiment of the present invention.

FIG. 2 is a diagram of an example of one embodiment of the present invention.

### DETAILED DESCRIPTION

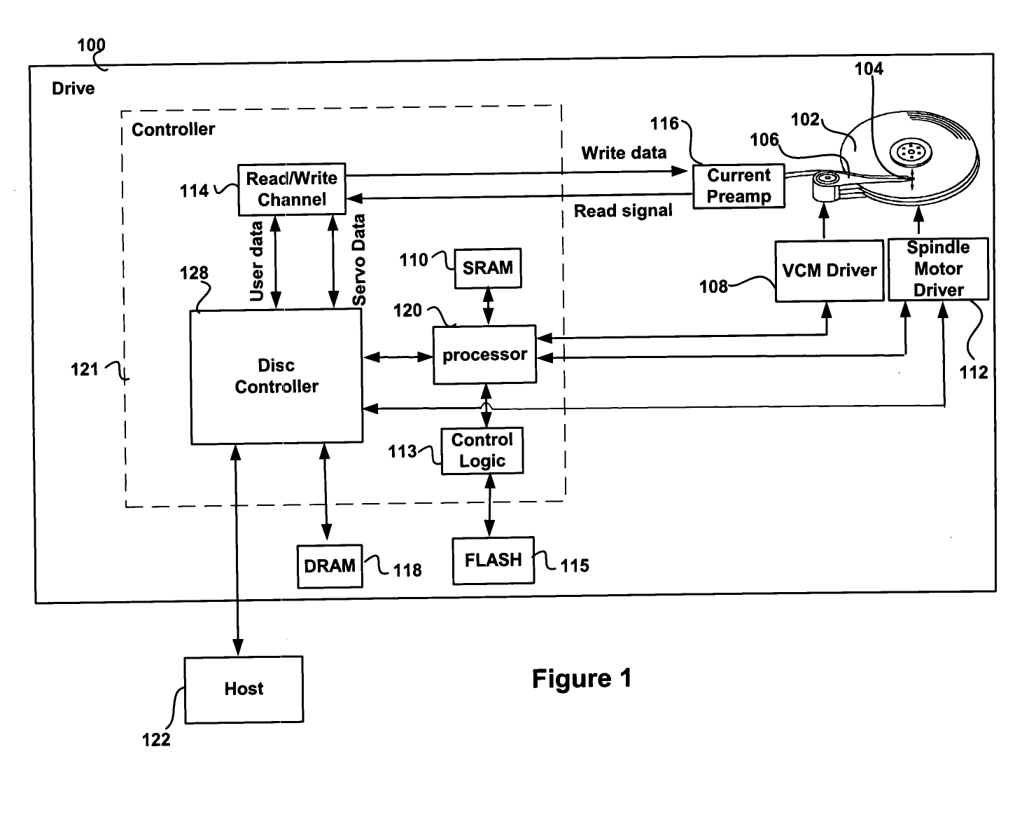

FIG. 1 shows a rotating media storage device 100 that can be used in accordance with one embodiment of the present invention. In this example, the rotating media storage device 100 is a hard disk drive. The rotating media storage device 100 includes at least one rotatable storage medium 102 capable of storing information on at least one surface. Numbers of disks and surfaces may vary by disk drive. In a magnetic disk drive, storage medium 102 is a magnetic disk. A closed loop servo system, including an actuator arm 106, can be used to position head 104 over selected tracks of disk 102 for reading or writing, or to move head 104 to a selected track during a seek operation. In one embodiment, head 104 is a magnetic transducer adapted to read data from and write data to the disk 102. In another embodiment, head 104 includes separate read elements and write elements. The read element can be a magnetoresistive (MR) head. Multiple head configurations may be used.

The servo system can include an actuator unit 108, which may include a voice coil motor driver to drive a voice coil motor (VCM) for rotating the actuator arm 106. The servo system can also include a spindle motor driver 112 to drive a spindle motor (not shown) for rotating of the disk 102. Controller 121 can be used to control the rotating media storage device 100. The controller 121 can include a number of arrangements. In one embodiment, the controller includes a disk controller 128, read/write channel 114, processor 120, SRAM 110, and control logic 113 on one or multiple chips. The controller can include fewer elements as well.

In one embodiment, the controller 121 is used to control the VCM driver 108 and spindle motor driver 112, to accept information from a host 122 and to control many disk functions. A host can be any device, apparatus, or system capable of utilizing the data storage device, such as a personal computer or mobile appliance. The controller 121 can include an interface controller in some embodiments for communicating with a host and in other embodiments, a separate interface controller can be used. The controller 121 can also include a servo controller, which can exist as circuitry within the drive or as an algorithm resident in the controller 121, or as a combination thereof. In other embodiments, an independent servo controller can be used.

Disk controller 128 can provide user data to a read/write channel 114, which can send signals to a current amplifier or pre-amp 116 to be written to the disk(s) 102, and can send servo signals to the microprocessor 120. Controller 121 can also include a memory controller to interface with memory such as the DRAM 118 and FLASH memory 115. FLASH memory 115 can be used as non-volatile memory to store code and data. DRAM 118 can be used as a buffer memory and to store the code to be executed along with the SRAM 110.

In one example, the controller 121 includes a processor 120 that interacts with control logic 113 to access a non-volatile memory, such as flash 115. In one embodiment, the flash 115 is a serial flash and control logic 113 is used for accessing the data for the serial flash 115. Host 122 can also interact with the processor 120. The controller 121 can also be used for the servo control, reading and writing of data to the disk and to other memories such as the SRAM 110 and the DRAM 118. In one embodiment, the controller 121 can include multiple processors. The processor 120 can implement some or all the control functions.

In one embodiment, code and data can be downloaded from the host 122, to the processor 120 then to the flash memory 115. Alternately, the flash memory 115 can be loaded before construction of the rotatable media storage device. The executable code can be loaded from the flash 115 to RAM, such as the SRAM 110 or DRAM 118, for execution by the processor 120. In some embodiments, code is executed directly from non-volatile memory.

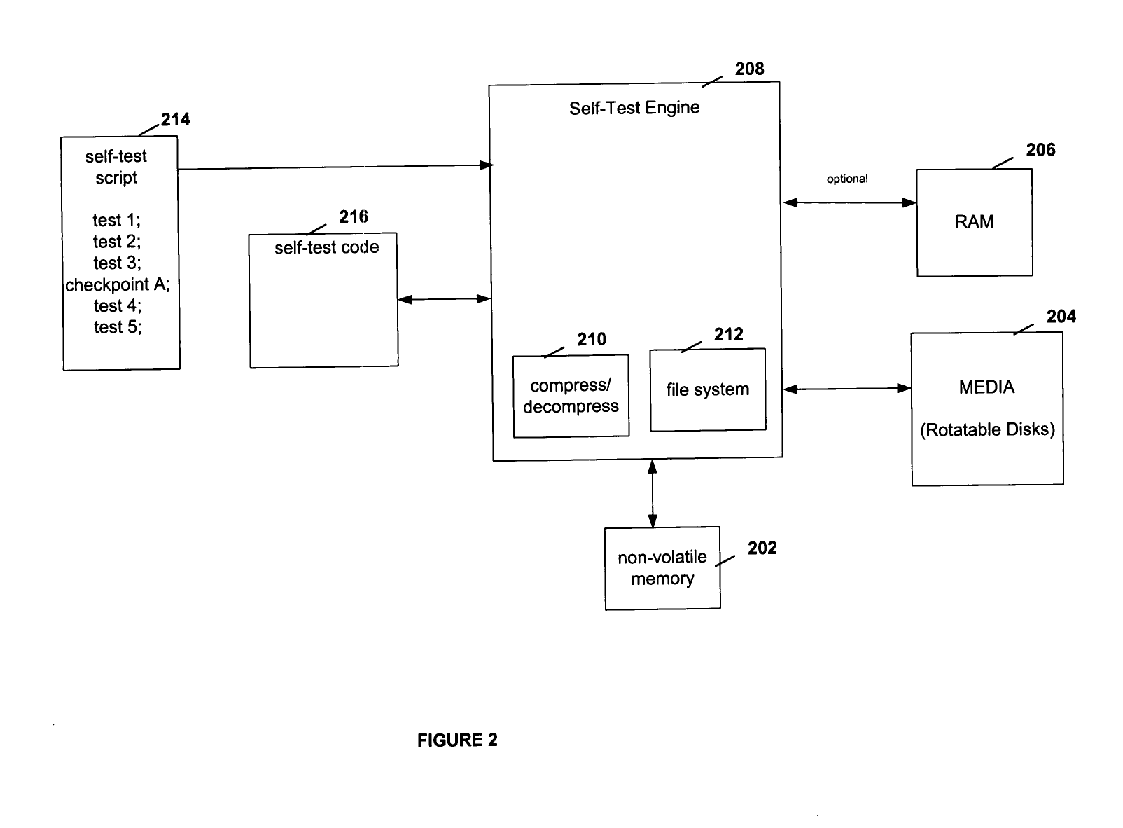

FIG. 2 illustrates an example of one embodiment of a hard disk drive which stores self-test data in the non-volatile memory 202 and rotatable disk 204. In one embodiment, the hard disk drive includes a rotatable disk 204 and adapted to store non-volatile memory 202 data. In one embodiment, self-test data is stored to the non-volatile memory 202 during the self-test. The self-test data can later be stored in the rotatable disk 204 during a later portion of the self-test. Examples of self-test data include disk defects, Finite Impulse Response (FIR) filter information, write compensation parameters, servo parameters, bias, KT/J information and burst information or other types of self-test data.

One reason the self-test data is not directly written to the rotatable disk 204 is that some of the self-test data concerns parameters needed to read and write information to the rotatable disk 204. This self-test data has to be determined before doing any writing to the disk. The parameter information can be stored on the flash until the parameter information is complete. Additionally, the flash can operate as a buffer to reduce the number of disk accesses required to store the self-test data.

The advantage storing self-test data in the non-volatile memory 202 rather than the RAM 206 is that if there is a power failure during the self-test and the self-test data is stored in the flash memory 202, the test need not be repeated. If the information is stored in a volatile memory, such as RAM 206 the self-test data will be lost and the test needs to be repeated. In one embodiment, the controller, such as the controller 121 shown in FIG. 1 is used. In one embodiment, a self-test engine 208 can be used to control the writing of the self-test data. The self-test engine 208 can be code run by the controller of the hard disk drive that controls the self-test.

In one embodiment, the system can generate self-test output to non-volatile memory before the media is available to read/write (for example, before it is servowritten). During a test that adjusts channel and preamp parameters, no heroic measures are required to handle media output differently. A record of the self-test can exists even if media is broken.

In one embodiment, the self-test engine includes compression/decompression code 210. This code can allow for the compression of the self-test data before it is written to the non-volatile memory 202. Compressing the self-test data allows for the efficient use of the space in the non-volatile memory 202. Compression helps reduce the size of the self-test data. The self-test data can be decompressed when it is written back to the media 204 or later, such as, when unloaded at end of all testing.

In one embodiment, the self-test engine 208 accesses the file system 212 which uses the same type of files for the rotatable disks 204 as the non-volatile memory 202. Using the same file system on the flash 202 and the media 204 simplifies the access and transfer of data. In one embodiment, if the self-test files are large and the non-volatile memory 202 fills up, portions of flash disk data can be written to the RAM 206 and then later the self-test data can be written from the non-volatile 202 and RAM 206 to the media 204.

In one embodiment, the self-test engine 208 executes a self-test script 214. The self test script can be stored in the flash. The self-test script includes a number of lines. Some lines can indicate a test and some lines can indicate a checkpoint. Each test can be associated with test code in the self-test code 216. The test code is code which runs the test. In one embodiment, the self-test engine 208 runs the test code 216. In one embodiment, the self-test code 216 can include a print function. The self-test engine interprets the print function as indicating self-test data to be stored in the flash 208. In one embodiment, the script 214 includes checkpoints. The checkpoints indicate to the self-test engine 208 to transfer self-test data from the non-volatile memory 202 to the media 204. In one embodiment, the checkpoints allow the system to be backed up after power failure. For example, in FIG. 2, after tests 1, 2 and 3, check point A result in the self-test data for tests 1, 2 and 3 being transferred from the non-volatile memory 202 to the media 204.

The checkpoint code can also cause the self-test data to be erased from the flash memory 202 after the transfer. An advantage of using the non-volatile memory 202 is that if the system crashes during test 3, even though the check point A has not occurred, the self-test data of test 1 and test 2 are stored in the non-volatile memory 202. Upon restart, the hard disk drives system can determine which tests are finished. This can be done by maintaining a pointer to the last completed test in the non-volatile memory 202. If the self-test data was stored in a RAM rather than the non-volatile memory 202 then each of the tests 1, 2 and 3 would need to be repeated upon a power failure before a checkpoint. When the self-test data is stored in non-volatile memory 202, only test 3 needs to be repeated. Since some tests in self-tests can take two to three hours or more, it is a significant problem if a power failure occurs, causing the repeat of tests.

Checkpoints can be used as a restart point. If test fails such as a (test power failure) at test 4 or 5, test 4 can be restarted at test. Upon a failure at test 3, the system can be restarted at test 1 next time.

In one embodiment, the check point A is placed in the script such that the results of the test 1, 2 and 3 do not fill the non-volatile memory 202. In one embodiment, as described above, if the non-volatile memory 202 is filled then the RAM 206 is used. The non-volatile memory 202 stores an indication of the last completed test for which the test data is completely stored in the non-volatile memory 202. In the case of power failure, the hard disk drive repeats any test partially stored in RAM. This means that if the self-test data of a completed, test 2 is stored both in the non-volatile memory 202 and the RAM 206, test 2 will be repeated after a power failure.

The foregoing description of preferred embodiments of the present invention has been provided for the purposes of illustration and description. It is not intended to be exhaustive or to limit the invention to the precise forms disclosed. Many modifications and variations will be apparent to one of the ordinary skill in the relevant arts. The embodiments were chosen and described in order to best explain the principles of the invention and its partial application, thereby enabling others skilled in the art to understand the invention for various embodiments and with various modifications that are suited to the particular use contemplated. It is intended that the scopes of the invention are defined by the claims and their equivalents.

1. A method of operating a hard disk drive comprising:
during self-test, storing self-test data into a non-volatile memory of the hard disk drive; and
optionally transferring the self-test data from the flash memory to a rotatable disk of the hard drive.

2. The method of claim 1, wherein self-test engine software is used to control the writing of the self-test data.

3. The method of claim 2, wherein the self-test engine executes a self-test script.

4. The method of claim 3, wherein lines of the self-test script are associated with self-test code.

5. The method of claim 4, wherein the self-test code includes “print” statements to record the results of testing, and wherein the self-test engine determines where to store the self-test data.

6. The method of claim 3, wherein the script includes checkpoint instructions.

7. The method of claim 6, wherein the checkpoint instructions indicate to the self-test engine to transfer self-test data from the flash memory to the rotatable disk.

8. The method of claim 6, wherein the checkpoint instructions also erases data after writing to rotating media.

9. The method of claim 1, wherein the self-test data is compressed before being stored in the non-volatile memory.

10. The method of claim 9, wherein the self-test data is decompressed before being written to the rotatable disk.

11. The method of claim 9, wherein a self-test engine compresses the self-test data.

12. The method of claim 1, wherein the self-test data is written into a RAM when there is not enough space in the flash memory.

13. The method of claim 1, wherein the non-volatile memory is a flash memory.

14. A method of operating a hard disk drive comprising:
during self-test, running a self-test script, the self-test script indicating tests and checkpoints;
when a test is indicated by the self-test script, running test code indicated by the script to do a test in self-test, the test code including statements indicating when to store self-test data;
when the statements in the test code indicate storing the self-test data, storing the self-test data into a non-volatile memory of the hard disk drive; and
when the script indicates a checkpoint, transferring the self-test data from the non-volatile memory to a rotatable disk of the hard disk drive.

15. The method of claim 14, wherein self-test engine software is used to control the writing of the self-test data.

16. The method of claim 15, wherein the statements are print statements that are interpreted by the self-test engine.

17. The method of claim 14, wherein the self-test data is compressed before being stored in the non-volatile memory.

18. The method of claim 17, wherein the self-test data is decompressed before being written to the rotatable disk.

19. The method of claim 17, wherein a self-test engine compresses the self-test data.

20. The method of claim 14, wherein the self-test data is written into a RAM when there is not enough space in the non-volatile memory.

21. The method of claim 14, wherein after checkpoint writes data to media, it erases it from non-volatile memory.

22. The method of claim 14, wherein the non-volatile memory is flash memory.
